(19) United States
(12) Patent Application Publication
(10) Pub. No.: US 2007/0187235 A1
(43) Pub. Date: Aug. 16, 2007

(54) Substrate holder and sputtering apparatus having same

(75) Inventor: Bor-Yuan Hsiao, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,854

(22) Filed: Oct. 13, 2006

(30) Foreign Application Priority Data
Dec. 23, 2005 (CN) 200510121252.0

(51) Int. Cl. C23C 14/00; C23C 16/00

(52) U.S. Cl. 204/298.11; 204/298.15; 118/728; 118/720

(57) ABSTRACT

A substrate holder configured for holding a substrate, the substrate having a peripheral side surface. The substrate holder includes a base configured for supporting the substrate thereon and at least one block provided on the base. The at least one block is structured and arranged for covering a predetermined area of the peripheral side surface of the substrate.

### TECHNICAL FIELD

The present invention relates to a substrate holder for use in a sputtering apparatus and a sputtering apparatus having the substrate holder.

### DESCRIPTION OF RELATED ART

Amorphous carbon (a-C) and hydrogenated amorphous carbon (a-C:H) films have attractive properties such as high hardness, low friction, electrical insulation, chemical inertness, optical transparency, biological compatibility, selective photon absorption, smoothness etc. For a number of years, these economically and technologically attractive properties have drawn almost unparalleled interest. Carbon films with very high hardness, high resistivity, and dielectric optical properties are now described as diamond-like carbon (DLC).

Several methods have been developed for producing DLC films such as: primary ion beam deposition of carbon ions (IBD); sputtering deposition of carbon with or without bombardment by an intense flux of ions (physical vapor deposition or PVD); deposition from an RF plasma, sustained in hydrocarbon gases, onto substrates negatively biased (plasma assisted chemical vapor deposition or PACVD).

A common feature of the aforementioned methods for producing DLC films is that the DLC film is deposited in tiny particles, for example, carbon ions or plasma that is composed of a variety of ions. Typically a plate is used for holding a substrate to be sputtered during the deposition of a DLC film from such particles in a manner such that the DLC film covers the whole surface of the substrate except those parts in contact with the plate. Referring to FIG. 9, a DLC film 82 is formed on a substrate 80. The DLC film 82 includes a wrap structure 822 at the corner of the substrate. The wrap structure 822 has greater inner stress than that of a plain DLC film, so the DLC film 82 often peels at the corners of the substrate 80.

Therefore there is a desire to develop a substrate holder for holding a substrate to be sputtered a DLC film thereon and a sputtering apparatus having the same, the substrate holder can prevent wrap structure being formed at a corner of a substrate.

### SUMMARY

In one embodiment, a substrate holder configured for holding a substrate, the substrate having a peripheral side surface. The substrate holder includes a base configured for supporting the substrate thereon and at least one block provided on the base. The at least one block is configured (i.e., structured and arranged) for covering a predetermined area of the peripheral side surface of the substrate.

In another embodiment, A sputtering apparatus for depositing material onto a substrate includes a vacuum chamber; a target holder; and a substrate holder. The target holder and the substrate holder are disposed in the vacuum chamber and face towards each other. The substrate holder is configured for holding the substrate, which includes a base configured for supporting the substrate thereon and at least one block provided on the base. The at least one block is structured and arranged for covering a predetermined area of the peripheral side surface of the substrate.

This and other features and advantages of the present invention as well as the preferred embodiments thereof and a substrate holder configured for holding a substrate and a sputtering apparatus having the same in accordance with the invention will become apparent from the following detailed description and the descriptions of the drawings.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention.

FIG. 1 is a cross sectional schematic view of a substrate holder in accordance with a first embodiment;

FIG. 2 is a cross sectional schematic view of a substrate holder in accordance with a second embodiment;

FIG. 3 is a cross sectional schematic view of a substrate holder in accordance with a third embodiment;

FIG. 4 is a schematic view of a baffle plate of the substrate holder in accordance with a fourth embodiment;

FIG. 5 is a sputtering apparatus in accordance with a fifth embodiment;

FIG. 6 is similar with FIG.1, but showing a substrate held in the substrate holder of FIG. 1;

FIG. 7 is similar with FIG. 6 but showing a DLC film deposited on the substrate;

FIG. 8 is a cross sectional schematic view of the DLC film deposited on the substrate, which has no wrap structure at the corner of the substrate after the substrate holder of FIG. 7 is removed; and

FIG. 9 is a cross sectional schematic view of a conventional DLC film deposited on a substrate.

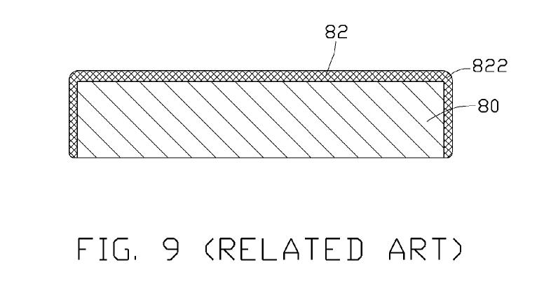

### DETAILED DESCRIPTION OF PREFERRED EMBODIMENTS

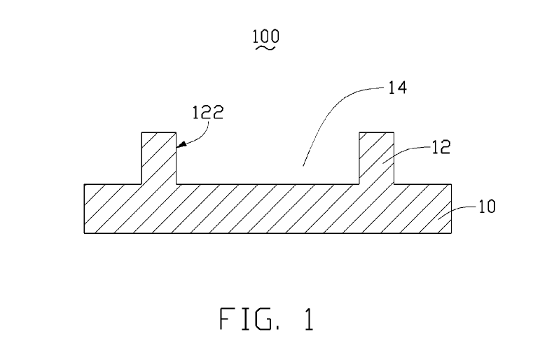

Referring to FIG. 1, a substrate holder 100 used in a sputtering apparatus in accordance with a first embodiment includes a base member 10 and at least a block, e.g. a baffle plate 12. The baffle plate 12 can be fixed on the base member 10 or integrally formed on the base member 10. The baffle plate 12 and the base member 12 co-orperatively define an open-ended chamber 14 configured for receiving a substrate to be sputtered therein. The baffle plate 12 includes an inner side surface 122 that is configured for tightly contacting with a peripheral side surface of the substrate. The baffle plate 12 has a height higher than that of the substrate. Preferably, the baffle plate 12 is higher than he substrate by a distance from about 1 micrometer to 10 micrometers. In the preferred embodiment, the baffle plate 12 covers the entire peripheral surface of the substrate, alternatively, the baffle plate can cover just the top corner of the substrate.

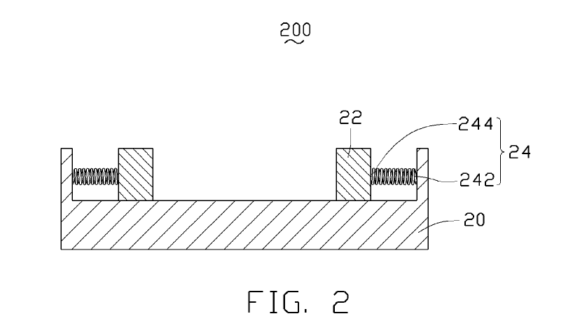

Referring to FIG. 2, a substrate holder 200 in accordance with a second embodiment is similar to that of the first embodiment, but also includes at least two springs 24. Each of the springs includes a first end 242 and a second end 244. The first end 242 is fixed on the base member 20 and the second end 244 is connected with a corresponding baffle plate 22. Each of the springs 24 is configured for pressing a corresponding baffle plate 22 against a substrate disposed on the base member 20. Preferably, at least two protrusions 26 are formed on the base member 20. The first end 232 is connected with a corresponding protrusion 26.

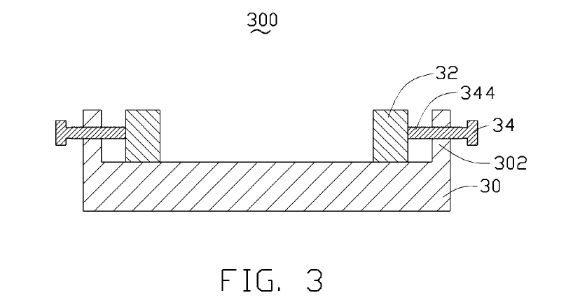

Referring to FIG. 3, a substrate holder 300 in accordance with a third embodiment is similar to that of the second embodiment except that the at least two springs are replaced by at least two screws 34. Each of the screws 34 is threadedly engaged with a corresponding protrusion 302 formed on the base member 30. Each of the screws 34 includes a first end 344. The first end 344 is configured for pressing a corresponding baffle plate 32 tightly against a substrate to be sputtered.

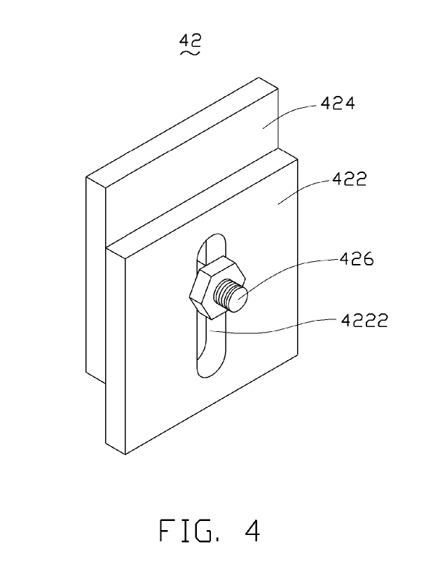

Referring to FIG. 4, a substrate holder in accordance with a fourth embodiment is similar to that of the first embodiment except that the baffle plate 42 includes a first plate 422 and a second plated 424 slidably connected with the first plate 422. The second plate 424 is configured for pressing against a substrate to be sputtered disposed on the base member 40. In the preferred embodiment, the first plate 422 and the second plate 424 both include a slit 4222 thereon. A screw 426 is used for fixing the second plate 424 and the first plate 422. The relative position of the first plate 422 and the second plate 424 can be adjusted using the slit and the screw 426. The adjustable height of the baffle plate 422 enables the substrate holder 400 to have better adaptability in processing a variety of substrates having varying thicknesses.

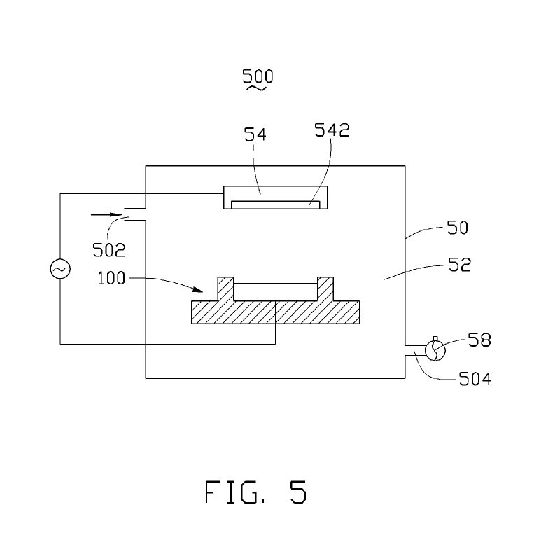

Referring to FIG. 5, a sputtering apparatus 500 having the substrate holder 100 in accordance with a fifth embodiment includes a reactor 50. The reactor 50 defines a discharge chamber 52 therein. A target holder 54 and the substrate holder 100 are disposed in the discharge chamber 52 face to each other. The target holder 54 is configured for holding a target material such as carbon or graphite thereon. The substrate holder 100 is spaced away from the target material 54 thereby defining an interspace region therebetween. The reactor 50 further defines an inlet 502 and an outlet 504. A vacuum pump 58 is configured for vacuumizing the discharge chamber 52 through the outlet 504.

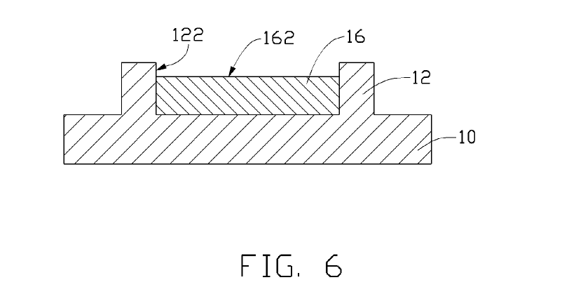

Referring to FIG. 6, a method for sputtering a DLC film with the sputtering apparatus 500 is described below in detail. A substrate 16 to be sputtered is positioned in the open-ended chamber 14 defined by the baffle plate 12 and base member 10. The substrate 16 includes a top surface 162 and peripheral side surface 164. The inner side surface 122 tightly contacts with the peripheral side surface 164. A discharge gas is input into the discharge chamber 52 after the discharge chamber 52 is vacuumized to 10-2 Pa or less using the vacuum pump 58. The discharge gas can be inert gas such as argon, neon etc. Then a voltage is applied between the target material 54 and the substrate 16 for ionizing the discharge gas to form a plasma, the plasma bombards the target material 54 and forms DLC-forming particles. Such particles deposit on the substrate and form a DLC film 18 thereon.

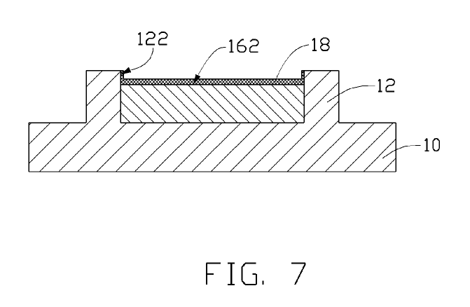

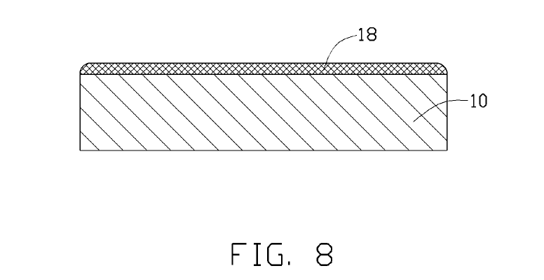

Referring to FIG. 7 the DLC film 18 covers both the inner side surface 122 and the top surface 162, but only a few particles can reach the area near to the corner of the substrate therefore the DLC film formed in that area is very loose and can easily be peeled off. Referring to FIG. 8, a DLC film 18 without wrap structure at the corners of the substrate 16 is formed after the substrate holder 100 is removed. Such a DLC film has better peel resistance at the corners of the substrate 16.

In the preferred embodiment, we take sputtering as an example to describe the method for depositing a DLC film, however, the substrate holder can also used in other methods for depositing DLC film such as IBD, PVD and chemical vapor deposition (CVD). In other words, we can surround the substrate with a baffle plate in the deposition of a DLC film on a substrate to obtain a DLC film without wrap structure at the corner of the substrate, so that the DLC film has a better peel resistance at the corners of the substrate.

It is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A substrate holder configured for holding a substrate, the substrate having a peripheral side surface, the substrate holder comprising: a base configured for supporting the substrate thereon and at least one block provided on the base, the at least one block being structured and arranged for covering a predetermined area of the peripheral side surface of the substrate.

2. The substrate holder as claimed in claim 1, wherein the block has a height relative to the base greater than a thickness of the substrate.

3. The substrate holder as claimed in claim 1, wherein the height of the block is 1 to 10 micrometers greater than the thickness of the substrate.

4. The substrate holder as claimed in claim 1, further comprising at least one resilient member, wherein the at least one block is movable on the base, the at least one resilient member is configured for pressing the at least one block against the peripheral surface of the substrate.

5. The substrate holder as claimed in claim 4, wherein the at least one resilient member comprises a spring having a first end and a second end, the first end being fixed on the base and the second end being coupled to the at least one block.

6. The substrate holder as claimed in claim 4, wherein the at least one resilient member comprises a screw, and the base comprises at least one corresponding protrusion formed thereon, the screw being threadedly engaged with the corresponding at least one protrusion.

7. The substrate holder as claimed in claim 1, wherein the at least block is structured and arranged for covering the entire peripheral surface of the substrate.

8. A sputtering apparatus for depositing material on a substrate, comprising: a vacuum chamber; a target holder; and a substrate holder as claimed in claim 1, the target holder and the substrate holder being disposed in the vacuum chamber and facing towards each other.

9. The sputtering apparatus as claimed in claim 8, wherein the block has a height relative to the base greater than a thickness of the substrate.

10. The sputtering apparatus as claimed in claim 8,wherein the height of the block is 1 to 10 micrometers greater than the thickness of the substrate.

11. The sputtering apparatus as claimed in claim 8, further comprising at least one resilient member, wherein the at least one block is movable on the base, the at least one resilient member is configured for pressing the at least one block against the peripheral surface of the substrate.

12. The sputtering apparatus as claimed in claim 11, wherein the at least one resilient member comprises a spring having a first end and a second end, the first end being fixed on the base and the second end being coupled to the at least one block.

13. The sputtering apparatus as claimed in claim 11, wherein the at least one resilient member comprises a screw, and the base comprises at least one corresponding protrusion formed thereon, the screw being threadly engaged with the corresponding at least one protrusion.

14. The sputtering apparatus as claimed in claim 8, wherein the at least block is structured and arranged for covering the entire peripheral surface of the substrate.
